(19) United States
(12) Patent Application Publication
(10) Pub. No.: US 2015/0097632 A1
(43) Pub. Date: Apr. 9, 2015

(54) VIBRATOR, OSCILLATOR, ELECTRONIC DEVICE, AND MOVING OBJECT

(71) Applicant: Seiko Epson Corporation, Tokyo (JP)

(72) Inventor: Akinori YAMADA, Ina (JP)

(21) Appl. No.: 14/505,579

(22) Filed: Oct. 3, 2014

(30) Foreign Application Priority Data
Oct. 8, 2013 (JP) 2013-210773

(51) Int. Cl. H03H 9/24; H02N 1/00; H03B 5/30; B81B 3/00

(52) U.S. Cl. CPC H03H 9/2447; B81B 3/0097; H02N 1/006; H03B 5/30
USPC 331/156; 310/300

(57) ABSTRACT

A MEMS vibrator includes: a base portion; a plurality of vibration reeds which extends from the base portion; a supporting portion which extends from a vibration node portion of the base portion; a fixing portion which is connected with the supporting portion; and a substrate in which the fixing portion is disposed on a main surface. The plurality of vibration reeds is separated from the substrate.

### BACKGROUND

1. Technical Field

The present invention relates to a vibrator, an oscillator provided with the vibrator, an electronic device, and a moving object.

2. Related Art

An electro-mechanical system structure (for example, a vibrator, a filter, a sensor, or a motor) provided with a mechanically movable structure which is called a micro electro mechanical system (MEMS) device which is formed by using semiconductor micro fabrication technology, is generally known. Among these, compared to an oscillator and a resonator using quartz crystal or a dielectric in the related art, since a MEMS vibrator is easy to be manufactured by incorporating a semiconductor circuit and advantageous in refinement and high functionality, the usage range thereof widens.

As representative examples of the MEMS vibrator in the related art, a comb type vibrator which vibrates in a direction parallel to a substrate surface provided with the vibrator, and a beam type vibrator which vibrates in a thickness direction of the substrate, are known. The beam type vibrator is a vibrator which has a fixed electrode formed on the substrate or a movable electrode separated and disposed on the substrate, and according to a method of supporting the movable electrode, a cantilevered beam type (clamped-free beam), a double-end supported beam type (clamped-clamped beam), or a both-ends free beam type (free-free beam) are known.

In the MEMS vibrator in a cantilevered beam type in JP-A-2012-85085, in a side surface portion of a first electrode provided on a main surface of the substrate, a corner of the side surface portion provided on a supporting portion side of a movable second electrode is formed substantially perpendicularly. For this reason, it is possible to reduce an effect of the variation of a vibration characteristic caused by a variation in an electrode shape, and to obtain a stable vibration characteristic.

However, the MEMS vibrator in JP-A-2012-85085 is advantageous in that the size thereof can be reduced since there is one supporting portion. However, since the mass of the supporting portion which fixes the cantilevered beam that vibrates in the thickness direction of the substrate is small, there is a problem in that a flexural vibration of the movable second electrode cannot be attenuated, the vibration of the beam is transmitted to the supporting portion and leaked to the entire substrate, a high Q value cannot be obtained, and a stable vibration characteristic or a desired vibration characteristic cannot be obtained.

### SUMMARY

An advantage of some aspects of the invention is to solve at least a part of the problems described above, and the invention can be implemented as the following forms or application examples.

### APPLICATION EXAMPLE 1

This application example is directed to a vibrator including: a substrate; a fixing portion which is fixed on the substrate; a base portion which is spaced and disposed on the substrate; a vibration reed which extends in a direction along the substrate from the base portion; and a supporting portion which connects the fixing portion and a connecting portion between the base portion and the vibration reed.

According to this application example, a vibration which is generated when the base portion and the vibration reed are separated from the substrate by the supporting portion and the base portion and the vibration reed are integrated, becomes a vibration node portion at a part where the base portion and the vibration reed are connected to each other, and the vibration node portion is configured to be supported by the supporting portion and fixed to the substrate. For this reason, it is possible to easily vibrate, and to suppress the vibration leakage from the vibration node portion. In particular, when the vibrator is configured as a beam type vibrator which vibrates in the thickness direction of the substrate, as a vibration displacement of the vibration reeds adjacent to each other is in directions opposite to each other, it is possible to greatly reduce the vibration displacement in the vibration node portion. For this reason, it is possible to suppress the vibration leakage generated from the vibration node portion supported by the supporting portion.

Therefore, according to this application example, it is possible to provide a vibrator having a high Q value, in which deterioration of vibration efficiency is suppressed or the vibration leakage is suppressed.

### APPLICATION EXAMPLE 2

This application example is directed to the vibrator according to the application example described above, wherein in a planar view of the substrate, the base portion is present between the plurality of supporting portions.

According to this application example, as the supporting portion which supports the vibration node portion is disposed to pinch the base portion at a facing position, the integrated base portion and the vibration reed can be supported to be well-balanced. For this reason, it is possible to improve impact resistance, and to provide a vibrator having high reliability.

### APPLICATION EXAMPLE 3

This application example is directed to the vibrator according to the application example described above, wherein at least one supporting portion is provided with a stress-relaxing portion.

According to this application example, as the supporting portion is provided with the stress-relaxing portion, it is possible to mitigate the transmission of stress generated by expansion and contraction of the substrate according to a change in the outside temperature to the integrated base portion and the vibration reed via the supporting portion. In addition, it is possible to suppress the vibration leakage which is transmitted via the supporting portion from the vibration node portion.

Therefore, according to this application example, it is possible to provide a vibrator having a stable vibration characteristic and a high Q value in which the vibration leakage is suppressed.

### APPLICATION EXAMPLE 4

This application example is directed to the vibrator according to the application example described above, wherein in a planar view of the substrate, the plurality of stress-relaxing portions is bent in the same rotating direction with respect to the center of the base portion.

According to this application example, the stress-relaxing portion provided in the supporting portion extends in the same rotating direction with respect to the center of the base portion. In other words, since the stress-relaxing portion is bent in a direction different from the direction in which the supporting portion extends from the base portion, even when the stress generated by the extension and contraction of the substrate according to the change in the outside temperature is transmitted via the fixing portion, it is easy to deform the stress-relaxing portion like a spring. For this reason, it is possible to mitigate the stress and suppress the transmission of the stress to the base portion and the vibration reed. In addition, the stress-relaxing portion also can attenuate the vibration leakage transmitted via the supporting portion from the vibration node portion, and suppress the transmission to the substrate.

### APPLICATION EXAMPLE 5

This application example is directed to the vibrator according to the application example described above, wherein the stress-relaxing portion includes a plurality of regions which is bent in a direction that intersects with a direction in which the supporting portion extends from the base portion.

According to this application example, since the plurality of regions is bent in a direction that intersects with a direction in which the supporting portion extends from the base portion, even when the stress generated by the extension and contraction of the substrate according to the change in the outside temperature is transmitted via the fixing portion, it is easy to deform the stress-relaxing portion like a coil spring. For this reason, it is possible to mitigate the stress and to suppress the transmission to the base portion and the vibration reed. In addition, the stress-relaxing portion also can attenuate the vibration leakage transmitted via the supporting portion from the vibration node portion, and suppress the transmission to the substrate.

### APPLICATION EXAMPLE 6

This application example is directed to the vibrator according to the application example described above, wherein the stress-relaxing portion has a curved portion.

According to this application example, since the stress-relaxing portion has the curved portion, even when the stress generated by the extension and contraction of the substrate according to the change in the outside temperature is transmitted via the fixing portion, the stress-relaxing portion is deformed like a coil spring. For this reason, it is possible to suppress the transmission to the base portion or the vibration reed. In addition, the stress-relaxing portion also can attenuate the vibration leakage transmitted via the supporting portion from the vibration node portion, and suppress the transmission to the substrate. Furthermore, since the stress-relaxing portion has the curved portion, the stress generated when an impact occurs from the outside does not occur locally. For this reason, a structure which is resistant to the impact is possible.

### APPLICATION EXAMPLE 7

This application example is directed to the vibrator according to the application example described above, wherein the stress-relaxing portion has an annular portion.

According to this application example, since the stress-relaxing portion has the annular portion, even when the stress generated by the extension and contraction of the substrate according to the change in the outside temperature is transmitted via the fixing portion, since the stress-relaxing portion is deformed by contracting or extending in the direction in which the supporting portion extends, it is possible to suppress the transmission to the base portion or the vibration reed. In addition, the stress-relaxing portion also can attenuate the vibration leakage transmitted via the supporting portion from the vibration node portion, and suppress the transmission to the substrate.

### APPLICATION EXAMPLE 8

This application example is directed to the vibrator according to the application example described above, wherein the stress-relaxing portions of the two supporting portions which are disposed to pinch the base portion at a facing position, are bent in a direction along each other.

According to this application example, since the stress-relaxing portions of the two supporting portions are bent in the direction along each other, the outside stress added to the adjacent vibration reed is equivalent, and a distortion generated by the difference of the outer stress added to each vibration reed can be attenuated. For this reason, it is possible to provide a vibrator having a high Q value in which the vibration leakage is suppressed.

### APPLICATION EXAMPLE 9

This application example is directed to the vibrator according to the application example described above, wherein in a planar view of the substrate, the two adjacent vibration reeds are different from each other in a phase of the vibration.

According to this application example, when the vibrator is configured as a beam type vibrator which vibrates in the thickness direction of the substrate, by reversing the phases of the vibration of the vibration reeds adjacent to each other, the vibration displacement can be in directions opposite to each other. For this reason, it is possible to greatly reduce the vibration displacement in the vibration node portion, to suppress the vibration leakage which is generated from the vibration node portion supported by the supporting portion, and to provide a vibrator having a high Q value.

### APPLICATION EXAMPLE 10

This application example is directed to the vibrator according to the application example described above, wherein the plurality of vibration reeds, which is different lengths of the width direction from each other, is provided.

According to this application embodiment, as the lengths (length in a direction that intersects with the direction which extends from the base portion) of the width direction of the vibration reeds are different from each other, even when the number of the vibration reeds is an odd number, for example, as the length of the width direction of one vibration reed is longer than the length of the width direction of two vibration reeds which pinch the base portion at a facing position, the vibration in the entire integrated base portion and vibration reed in the vibration node portion is balanced. For this reason, it is possible to suppress the vibration leakage, and to provide a vibrator having a high Q value.

### APPLICATION EXAMPLE 11

This application example is directed to an oscillator including the vibrator according to the application example described above.

According to this application example, as the vibrator having a high Q value is provided, it is possible to provide an oscillator having higher functionality.

### APPLICATION EXAMPLE 12

This application example is directed to an electronic device including the vibrator according to the application example described above.

According to this application example, as the vibrator having a high Q value is used as the electronic device, it is possible to provide an electronic device having higher functionality.

### APPLICATION EXAMPLE 13

This application example is directed to a moving object including the vibrator according to application example described above.

According to this application example, as the vibrator having a high Q value is used as the moving object, it is possible to provide a moving object having higher functionality.

### BRIEF DESCRIPTION OF THE DRAWINGS

The invention will be described with reference to the accompanying drawings, wherein like numbers reference like elements.

FIGS. 1A to 1D are plan views and cross-sectional views of a vibrator according to an embodiment.

FIGS. 2A to 2G are flow charts illustrating a manufacturing method of the vibrator in order according to the embodiment.

FIG. 3 is a schematic view illustrating a configuration example of an oscillator provided with the vibrator according to the embodiment.

FIG. 4A is a perspective view illustrating a configuration of a mobile-type personal computer as an example of an electronic device. FIG. 4B is a perspective view illustrating a configuration of a mobile phone as an example of the electronic device.

FIG. 5 is a perspective view illustrating a configuration of a digital still camera as an example of the electronic device.

FIG. 6 is a schematic perspective view illustrating a vehicle as an example of a moving object.

FIGS. 7A to 7D are plan views illustrating an example of a variation of an upper electrode in a vibrator according to Modification Example 1.

FIGS. 8A to 8C are plan views illustrating an example of a variation of a stress-relaxing portion in a vibrator according to Modification Example 2.

FIGS. 9A and 9B are plan views illustrating an example of a variation of a stress-relaxing portion in a vibrator according to Modification Example 3.

FIGS. 10A and 10B are plan views illustrating an example of a variation of a stress-relaxing portion having two supporting portions in a vibrator according to Modification Example 4.

### DESCRIPTION OF EXEMPLARY EMBODIMENTS

Hereinafter, embodiments which implement the invention will be described with reference to the drawings. Hereinafter, embodiments of the invention are described, but the invention is not limited thereto. In addition, in each drawing below, there is a case where the dimensions are different from the real dimensions for easy understanding.

### Embodiment

### Vibrator

First, a MEMS vibrator 100 will be described as a vibrator according to the embodiment.

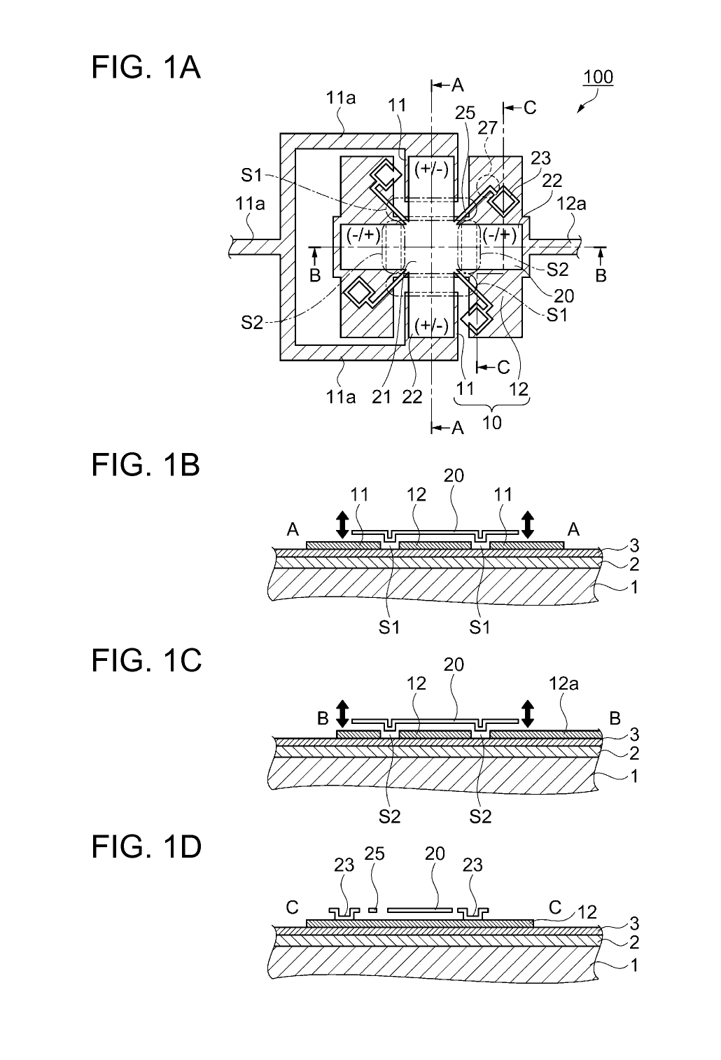

FIG. 1A is a plan view of the MEMS vibrator 100. FIG. 1B is a cross-sectional view along line A-A in FIG. 1A. FIG. 1C is a cross-sectional view along line B-B in FIG. 1A. FIG. 1D is a cross-sectional view along line C-C in FIG. 1A.

The MEMS vibrator 100 is an electrostatic beam type vibrator which is provided with a fixed electrode (lower electrode 10) formed on a substrate 1 and a movable electrode (upper electrode 20) formed to be separated from the substrate 1 and the fixed electrode. The movable electrode is formed to be separated from the substrate 1 and the fixed electrode as a sacrificing layer stacked on a main surface of the substrate 1 and the fixed electrode is etched thereon.

In addition, the sacrificing layer is a layer once formed by an oxide film or the like, and is removed by etching after forming a necessary layer above and below or in the vicinity thereof. As the sacrificing layer is removed, a necessary gap or a cavity is formed between each layer above and below or in the vicinity thereof, and a necessary structure is formed to be separated.

A configuration of the MEMS vibrator 100 will be described hereinafter. A manufacturing method of the MEMS vibrator 100 will be described in the embodiment which will be described below.

The MEMS vibrator 100 is configured to have the substrate 1, the lower electrode 10 (first lower electrode 11, second lower electrode 12) and a fixing portion 23 provided on the main surface of the substrate 1, a supporting portion 25 which extends from a base portion 21 of the upper electrode 20 and has a stress-relaxing portion 27, an upper electrode 20 (integrated with the base portion 21 and a vibration reed 22) as a movable electrode which is separated from the substrate 1 and supported by the supporting portion 25, and the like.

For the substrate 1, a silicon substrate is used as a suitable example. On the substrate 1, an oxide film 2 and a nitride film 3 are stacked in order. In an upper portion of the main surface (surface of the nitride film 3) of the substrate 1, the lower electrode 10 (first lower electrode 11, second lower electrode 12), the upper electrode 20, the fixing portion 23, the supporting portion 25, and the like are formed.

In addition, here, in a thickness direction of the substrate 1, a direction in which the oxide film 2 and the nitride film 3 are stacked in order on the main surface of the substrate 1 is described as an upward direction.

In the lower electrode 10, the second lower electrode 12 is a fixed electrode which fixes the fixing portion 23 onto the substrate 1, imparts an electric potential to the upper electrode 20 via the fixing portion 23 and the supporting portion 25, and is formed in an H shape as illustrated in FIG. 1A by patterning a first conductor layer 4 stacked on the nitride film 3 by photolithography (including etching processing. The same hereinafter). In addition, the second lower electrode 12 is connected with an outer circuit (not illustrated) by wiring 12a.

The fixing portion 23 is provided at each of the four end portions of the H-shaped second lower electrode 12. The fixing portion 23 is formed by patterning a second conductor layer 5 which is stacked via the sacrificing layer stacked on an upper layer of the first conductor layer 4 by photolithography. In addition, a part of the fixing portion 23 is directly stacked on the second lower electrode 12 through an opening portion provided on the sacrificing layer.

The first conductor layer 4 and the second conductor layer 5 respectively use conductive polysilicon as a suitable example, but the embodiment is not limited thereto.

The upper electrode 20 is configured to have the base portion 21 and the plurality of vibration reeds 22 which extends in a radial shape from the base portion 21. Here, “extend in a radial shape” means extending toward directions different from each other. More specifically, FIG. 1A illustrates a movable electrode which shows a cross shape of the four vibration reeds 22 which extend from the base portion 21 of the upper electrode 20 and is supported by the four supporting portions 25 which extend from the four fixing portions 23 provided with the upper electrode 20 in the vicinity thereof.

The upper electrode 20 is formed by patterning the second conductor layer 5 which is stacked via the sacrificing layer stacked on the upper layer of the first conductor layer 4 by photolithography. In other words, the four fixing portions 23, the four supporting portions 25, and the upper electrode 20 are integrally formed. In addition, the H-shaped second lower electrode 12 and the cross-shaped upper electrode 20 are disposed to be overlapped so that center parts thereof are substantially matched with each other when the substrate 1 is viewed from a planar view, and the two vibration reeds 22 which extend in a lateral direction (B-B direction) from the base portion 21 of the upper electrode 20 are disposed to be overlapped with the H-shaped second lower electrode 12 (remove a part of a slit S2 which will be described later).

The plurality of supporting portions 25 is disposed to pinch the base portion 21 at a facing position, and has the stress-relaxing portion 27 between the base portion 21 and the fixing portion 23. In the stress-relaxing portion 27, one end portion of a part which extends in a direction that intersects with a direction that extends from the base portion 21 is connected to an end portion opposite to the base portion 21 of the supporting portion 25, and the other end portion of the part is connected to the fixing portion 23. In addition, a part of the stress-relaxing portion 27 provided in the four supporting portions 25 extends in a rotating direction which is the same with respect to the center of the base portion 21 in a planar view. In other words, the supporting portion 25 which extends from the base portion 21 is bent in the middle, and the bent part functions as the stress-relaxing portion 27. Extending in the same rotating direction means being bent toward the same direction.

According to the configuration, even when stress generated by the extension and contraction of the substrate according to a change in the outside temperature is transmitted via the fixing portion 23, since the stress-relaxing portion 27 is deformed like a plate spring, it is possible to mitigate the transmission to the base portion 21 or the vibration reed 22. In addition, the stress-relaxing portion 27 may not be provided in all of the supporting portions 25, and may be provided in at least one supporting portion 25.

In the lower electrode 10, the first lower electrode 11 is a fixed electrode to which an AC voltage is applied between the first lower electrode 11 and the upper electrodes 20 overlapped when the substrate 1 is viewed from a planar view, and is formed by patterning the first conductor layer 4 stacked on the nitride film 3 by photolithography. When FIG. 1A is viewed from a front view, the first lower electrode 11 is provided at two locations to be overlapped with the two vibration reeds 22 which extend in a longitudinal direction (A-A direction) from the base portion 21 of the upper electrode 20, and is connected with the outer circuit by wiring 11a.

The first lower electrode 11 is formed by the first conductor layer 4 which is the same layer as the second lower electrode 12. Therefore, the first lower electrode 11 is required to be electrically insulated between the first lower electrode 11 and the second lower electrode 12 as the fixed electrode which imparts the electric potential to the upper electrode 20, and each pattern (first lower electrode 11 and second lower electrode 12) is separated. A step difference (unevenness) of a gap for the separation is transferred to the upper electrode 20 which is formed by the second conductor layer 5 stacked via the sacrificing layer stacked on the upper layer of the first conductor layer 4, in an uneven shape. In particular, as illustrated in FIGS. 1A and 1B, in a part of a separation portion (slit S1) of the pattern, the uneven shape is formed in the upper electrode 20.

In the MEMS vibrator 100, in order to prevent occurrence of a difference in stiffness, by the vibration reed 22 which extends in the longitudinal direction (A-A direction) from the base portion 21 of the upper electrode 20 and the vibration reed 22 which extends in the lateral direction (B-B direction), a dummy slit pattern is provided in the second lower electrode 12. In particular, like the uneven shape reflected to the two vibration reeds 22 in which the slit S1 extends in the longitudinal direction (A-A direction) of the upper electrode 20, a dummy slit S2 which generates the uneven shape in the two vibration reeds 22 in which the slit S2 extends in the lateral direction (B-B direction) of the upper electrode 20, is provided in the second lower electrode 12 in which the slit S2 extends in the lateral direction (B-B direction) in an area where the upper electrode 20 is overlapped. In other words, a width (length of B-B direction) of the slit S2 is substantially the same as a width (length of A-A direction) of the slit S1. The slit S2 is formed so that a distance from a center point of the upper electrode 20 to the slit S2 is substantially the same as the distance from a center point of the upper electrode 20 to the slit S1, in a planar view.

As the dummy slit S2 is provided in this manner, the upper electrode 20 is configured to include an uneven portion. In addition, since the slit S2 is not formed for electrically insulating the second lower electrode 12, in a planar view, in the area where both end portions of the slit S2 are not overlapped with the upper electrode 20, the second lower electrode 12 is disposed to be continued.

In the configuration, the MEMS vibrator 100 is configured as an electrostatic vibrator. By the AC voltage applied between the first lower electrode 11 and the upper electrode 20 via the wirings 11a and 12a from the outer circuit, a tip end area of the four vibration reeds 22 of the upper electrode 20 vibrates as an antinode of the vibration. In FIG. 1A, a (+/−) signal illustrates a part which vibrates in a vertical direction (thickness direction of the substrate 1) as the antinode of the vibration, including a phase relation of the vibration, and the phases of the adjacent vibration reeds 22 are different. For example, the signal illustrates a case where the +vibration reed 22 moves in the upward direction (direction away from the substrate 1) and the adjacent vibration reed 22 moves in the downward direction (direction which approaches the substrate 1).

Here, the two vibration reeds 22 which pinch the base portion 21 at a facing position are regarded as a beam in a substantially rectangular shape including the base portion 21. For this reason, when the tip ends of the two vibration reeds 22 vibrate in the upward direction, the base portion 21 vibrates in the downward direction. Accordingly, a flexural vibration having a displacement in the thickness direction of the vibration reed 22 is generated. In addition, the adjacent vibration reeds 22, the base portion 21, and the beam which is configured by the vibration reeds 22 which pinch the base portion 21 at a facing position generate the flexural vibration, in which the base portion 21 vibrates in the upward direction when the tip ends of the two vibration reeds 22 vibrate in the downward direction. For this reason, when the two beams vibrate at the same time, the displacement of the base portion 21 in a vertical direction is offset and the vibration is suppressed, and the area where the base portion 21 and the vibration reed 22 are connected to each other becomes a vibration node portion. Accordingly, in the vibration node portion, as the vibration of the entire upper electrode 20 is balanced, by supporting the part, it is possible to simply provide the electrostatic beam type vibrator which has higher vibration efficiency and suppressed vibration leakage.

### Manufacturing Method

Next, a manufacturing method of the vibrator (MEMS vibrator 100) according to the embodiment will be described. In addition, according to the description, the same configuration location described above will use the same reference numerals and the repeating description thereof will be omitted.

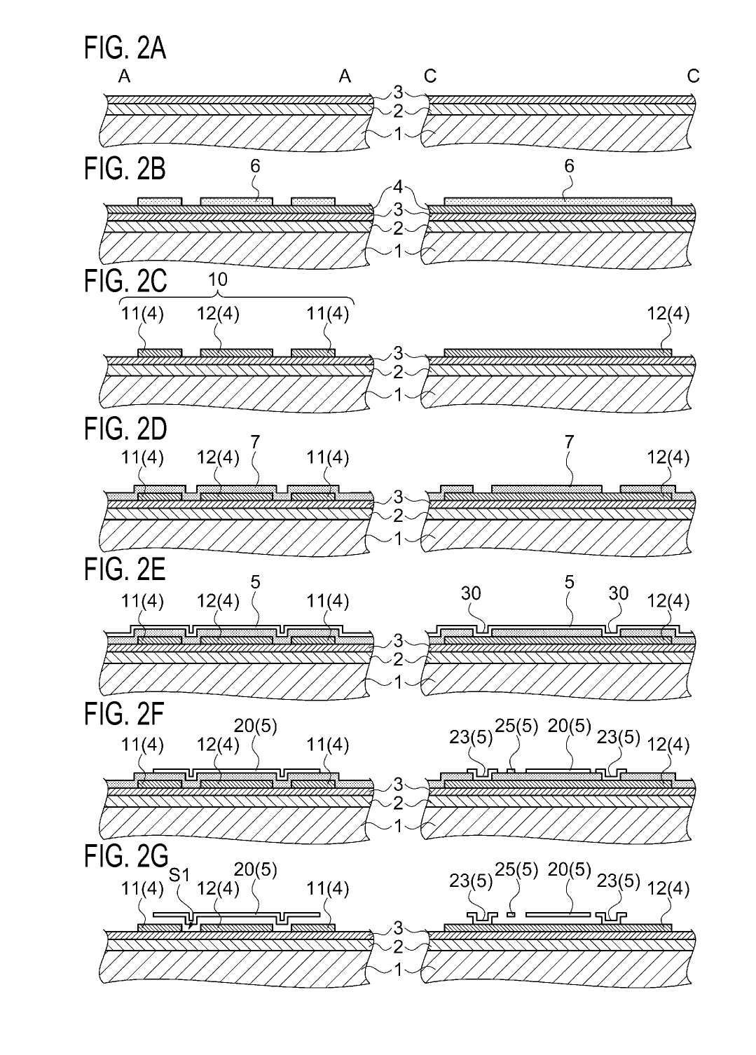

FIGS. 2A to 2G are flow charts illustrating the manufacturing process of the MEMS vibrator 100 in order. States of the MEMS vibrator 100 in each process will be illustrated in the cross-sectional view taken along line A-A in FIG. 1A and a cross-sectional view taken along line C-C in FIG. 1A according to the embodiment.

FIG. 2A: The substrate 1 is prepared and the oxide film 2 is stacked on the upper portion of the main part. The oxide film 2 is formed by a general local oxidation of silicon (LOCOS) as an element separation layer of a semiconductor process, but may be an oxide film according to generation of the semiconductor process, for example, according to a shallow trench isolation (STI) method.

Next, the nitride film 3 is stacked as an insulating layer. Silicon nitride (Si₃N₄) forms the nitride film 3 by a low pressure chemical vapor deposition (LPCVD). The nitride film 3 has a resistance with respect to buffered hydrogen fluoride as an etchant which is used at a time of release etching of a sacrificing layer 7, and functions as an etching stopper.

FIGS. 2B and 2C: Next, as a first layer forming process, first of all, the first conductor layer 4 is stacked on the nitride film 3. The first conductor layer 4 is a polysilicon layer which is configured to have the lower electrode 10 (first lower electrode 11, second lower electrode 12), the wirings 11a and 12a (refer to FIG. 1A), or the like, and has a predetermined conductivity by injecting ions, such as boron (B) or phosphorus (P) after the stacking. Next, by coating a resist 6 on the first conductor layer 4 and patterning by photolithography, the first lower electrode 11, the second lower electrode 12, and the wirings 11a and 12a are formed. In the first layer forming process, when the substrate 1 is viewed from a planar view after a second layer forming process, the lower electrode 10 is formed in advance to be overlapped with the upper electrode 20, in other words, the first lower electrode 11 and the second lower electrode 12 are formed.

FIG. 2D: Next, the sacrificing layer 7 is stacked to cover the lower electrode 10 and the wirings 11a and 12a. The sacrificing layer 7 is a sacrificing layer which forms a gap between the first lower electrode 11 and the second lower electrode 12, and the upper electrode 20, and which separates the upper electrode 20. The sacrificing layer 7 forms a film according to a chemical vapor deposition (CVD) method. In the stacked sacrificing layer 7, an unevenness due to a step difference between the patterned first lower electrode 11 and the second lower electrode 12 or the like appears.

FIG. 2E: Next, the sacrificing layer 7 is patterned by photolithography, and an opening portion 30 which exposes a part of the second lower electrode 12 is formed. In the opening portion 30, a connection area, in which the fixing portion 23 is connected with the second lower electrode 12 and fixed, is formed. Since the connection area is an area in which the upper electrode 20 is supported to the substrate 1 via the supporting portion 25, an area in which a necessary stiffness can be obtained is open.

FIG. 2F: Next, as the second layer forming process, first of all, the second conductor layer 5 is stacked to cover the sacrificing layer 7 and the opening portion 30. The second conductor layer 5 is the same polysilicon layer as the first conductor layer 4, and forms the upper electrode 20, the fixing portion 23, and the supporting portion 25 by patterning by photolithography after the stacking. As illustrated in FIG. 1A, the shape of the upper electrode 20 is formed so that the vibration reed 22 extends in a radial shape from the base portion 21 in the center of the upper electrode 20, as an electrode which has an area in which the first lower electrode 11 and the second lower electrode 12 are overlapped when the substrate 1 is viewed from a planar view. In addition, the predetermined conductivity is imparted to the area of the upper electrode 20 which excludes the fixing portion 23 and the supporting portion 25, by injecting ions, such as boron (B) or phosphorus (P), after the stacking.

FIG. 2G: Next, by bleaching the substrate 1 by the etchant (buffered hydrogen fluoride) and etching-removing (release etching) the sacrificing layer 7, the gap between the first lower electrode 11 and the second lower electrode 12, and the upper electrode 20 is formed, and the upper electrode 20 is separated.

According to the description above, the MEMS vibrator 100 is formed.

In addition, it is preferable that the MEMS vibrator 100 is disposed in a cavity portion which is sealed in a decompression state. For this reason, in manufacturing the MEMS vibrator 100, the sacrificing layer for forming the cavity portion, a side wall portion which surrounds the sacrificing layer, a sealing layer which forms a lid of the cavity portion, or the like, are formed to be combined, but the description thereof is omitted here.

As described above, according to the MEMS vibrator 100 in the embodiment, it is possible to obtain the following effects.

In the upper electrode 20, since the vibration node portion of the base portion 21 is supported by the supporting portion 25, the vibration of the entire upper electrode 20 is balanced by the vibration node portion, and it is possible to provide an electrostatic beam type vibrator which has higher vibration efficiency and a high Q value in which the vibration leakage is suppressed.

In addition, since the stress-relaxing portion 27 is provided in the supporting portion 25, even when the stress generated by the extension and contraction of the substrate according to the change in the outside temperature is transmitted via the fixing portion 23, the stress-relaxing portion 27 is deformed like a spring, and it is possible to mitigate the transmission to the entire upper electrode 20 which is integrated by the base portion 21 and the vibration reed 22. For this reason, it is possible to provide a beam type vibrator which has a stable vibration characteristic with respect to the outer temperature change and a high Q value.

### Oscillator

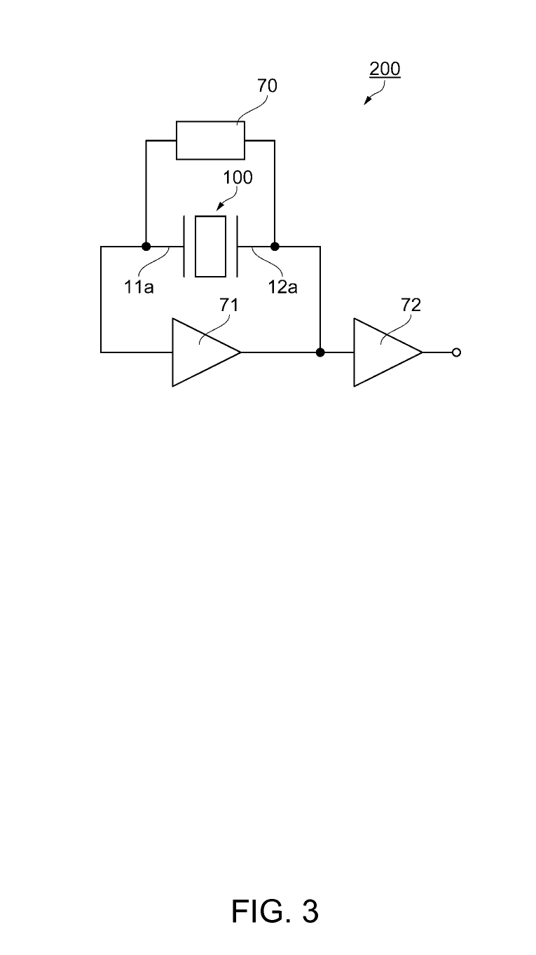

Next, an oscillator 200 which employs the MEMS vibrator 100 as an oscillator according to an embodiment of the invention will be described based on FIG. 3.

FIG. 3 is a schematic view illustrating a configuration example of the oscillator provided with the MEMS vibrator 100 according to the embodiment of the invention. The oscillator 200 is configured to have the MEMS vibrator 100, a bypass circuit 70, an amplifiers 71 and 72, or the like.

The bypass circuit 70 is a circuit which is connected to the wirings 11a and 12a of the MEMS vibrator 100, and applies the AC voltage in which a predetermined electric potential is bypassed in the MEMS vibrator 100.

The amplifier 71 is a feedback amplifier which is connected to the wirings 11a and 12a of the MEMS vibrator 100, in parallel with the bypass circuit 70. By performing the feedback amplification, the MEMS vibrator 100 is configured as the oscillator 200.

The amplifier 72 is a buffer amplifier which outputs an oscillation waveform.

According to the embodiment, as the vibrator having a high Q value is provided as the oscillator, it is possible to provide an oscillator having higher functionality.

### Electronic Device

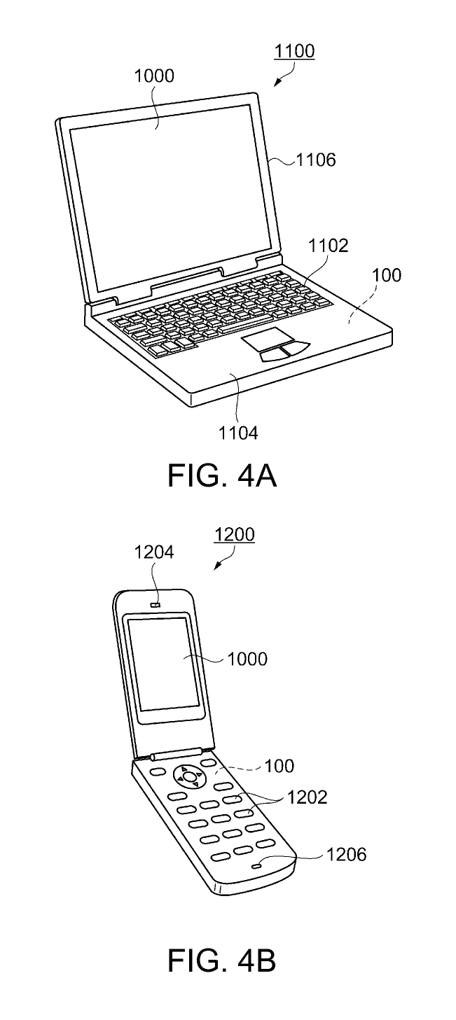

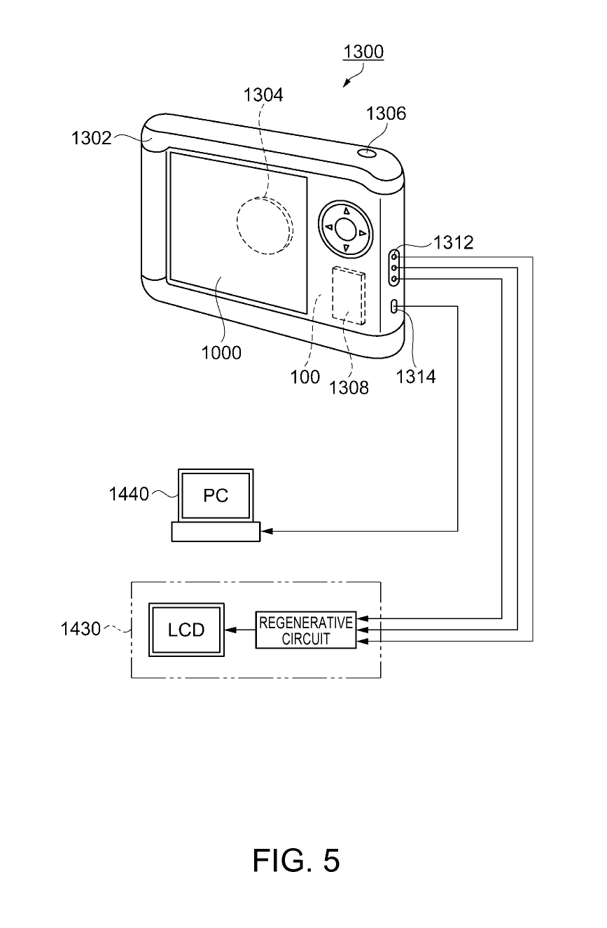

Next, an electronic device which employs the MEMS vibrator 100 as an electronic component according to an embodiment of the invention will be described based on FIGS. 4A, 4B, and 5.

FIG. 4A is a schematic perspective view illustrating a configuration of a mobile-type (or note-type) personal computer as the electronic device provided with the electronic component according to the embodiment of the invention. In the drawing, a personal computer 1100 is configured to have a main body portion 1104 provided with a keyboard 1102 and a display unit 1106 provided with a display portion 1000. The display unit 1106 is supported to be rotatable via a hinge structure portion with respect to the main body portion 1104. In the personal computer 1100, the MEMS vibrator 100 as the electronic component which functions as a filter, a resonator, a reference clock, or the like is embedded.

FIG. 4B is a schematic perspective view illustrating a configuration of a mobile phone (including PHS) as the electronic device provided with the electronic component according to the embodiment of the invention. In the drawing, a mobile phone 1200 is provided with a plurality of operation buttons 1202, an ear piece 1204, and a mouth piece 1206. The display portion 1000 is disposed between the operation button 1202 and the ear piece 1204. In the mobile phone 1200, the MEMS vibrator 100 as the electronic component (timing device) which functions as the filter, the resonator, an angular velocity sensor, or the like is embedded.

FIG. 5 is a schematic perspective view illustrating a configuration of a digital still camera as the electronic device provided with the electronic component according to the embodiment of the invention. In addition, in the drawing, a connection with an outer device is also simply illustrated. A digital still camera 1300 performs photoelectric conversion of an optical image of a subject by a photographing element, such as a charged coupled device (CCD), and generates a photographing signal (image signal).

On a rear surface of a case (body) 1302 in the digital still camera 1300, the display portion 1000 is provided, and a display is performed based on the photographing signal by the CCD. The display portion 1000 functions as a finder which displays the subject as an electronic image. In addition, on a front surface side (back surface side in the drawing) of the case 1302, a light receiving unit 1304 including an optical lens (photographing optical system) or the CCD is provided.

When a photographer confirms a subject image displayed on the display portion 1000 and pushes a shutter button 1306, the photographing signal of the CCD at that moment is sent and stored in a memory 1308. In addition, in the digital still camera 1300, on a side surface of the case 1302, a video signal output terminal 1312 and a data communication input and output terminal 1314 are provided. As illustrated in the drawing, a television monitor 1430 is connected to the video signal output terminal 1312, and a personal computer 1440 is connected to the data communication input and output terminal 1314, as necessary, respectively. Furthermore, according to a predetermined operation, the photographing signal accommodated in the memory 1308 is output to the television monitor 1430 or the personal computer 1440. In the digital still camera 1300, the MEMS vibrator 100 is embedded as the electronic component which functions as the filter, the resonator, the angular velocity sensor, or the like.

As described above, as the vibrator having a high Q value is used as the electronic component, it is possible to provide an electronic device having higher functionality.

In addition, the MEMS vibrator 100 as the electronic component according to the embodiment of the invention can be employed in the electronic device, such as an ink jet type discharging apparatus (for example, an ink jet printer), a laptop type personal computer, a television, a video camera, a car navigation apparatus, a pager, an electronic organizer (including an electronic organizer having a communication function), an electronic dictionary, an electronic calculator, an electronic game device, a work station, a video telephone, a television monitor for crime prevention, an electronic binoculars, a POS terminal, a medical device (for example, an electronic thermometer, a sphygmomanometer, a blood sugar meter, an electrocardiograph, an ultrasonic diagnostic equipment, and an electronic endoscopy), a fish finder, various measurement apparatuses, meters (for example, meters of the vehicle, an aircraft, or a vessel) or a flight simulator, in addition to the personal computer 1100 (mobile type personal computer) in FIG. 4A, the mobile phone 1200 in FIG. 4B, and the digital still camera 1300 in FIG. 5.

### Moving Object

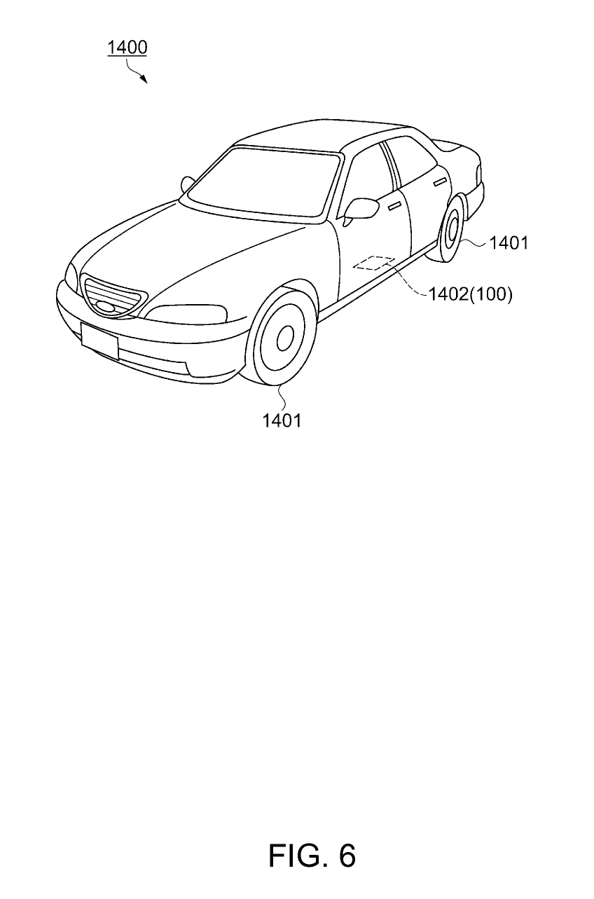

Next, a moving object which employs the MEMS vibrator 100 as the vibrator according to the embodiment of the invention will be described based on FIG. 6.

FIG. 6 is a schematic perspective view illustrating a vehicle 1400 as the moving object provided with the MEMS vibrator 100. In the vehicle 1400, a gyro sensor configured to have the MEMS vibrator 100 according to the invention is mounted. For example, as illustrated in FIG. 6, in the vehicle 1400 as the moving object, an electronic control unit 1402, in which the gyro sensor that controls a tire 1401 is embedded, is mounted. In addition, as another example, the MEMS vibrator 100 can be employed widely in an electronic control unit (ECU), such as a keyless entry, an immobilizer, a car navigation system, a car air conditioner, an anti-lock brake system (ABS), an air bag, a tire pressure monitoring system (TPMS), an engine control, a battery monitor of a hybrid vehicle or an electric vehicle, or a vehicle posture control system.

As described above, as the vibrator having a high Q value is used as the moving object, it is possible to provide a moving object having higher functionality.

In addition, the invention is not limited to the above-described embodiment, and various modifications or improvements are possible in the above-described embodiment. Modification examples will be described hereinafter. Here, the same configuration part as the above-described embodiment will use the same reference numerals and the repeated description thereof will be omitted.

### Modification Example 1

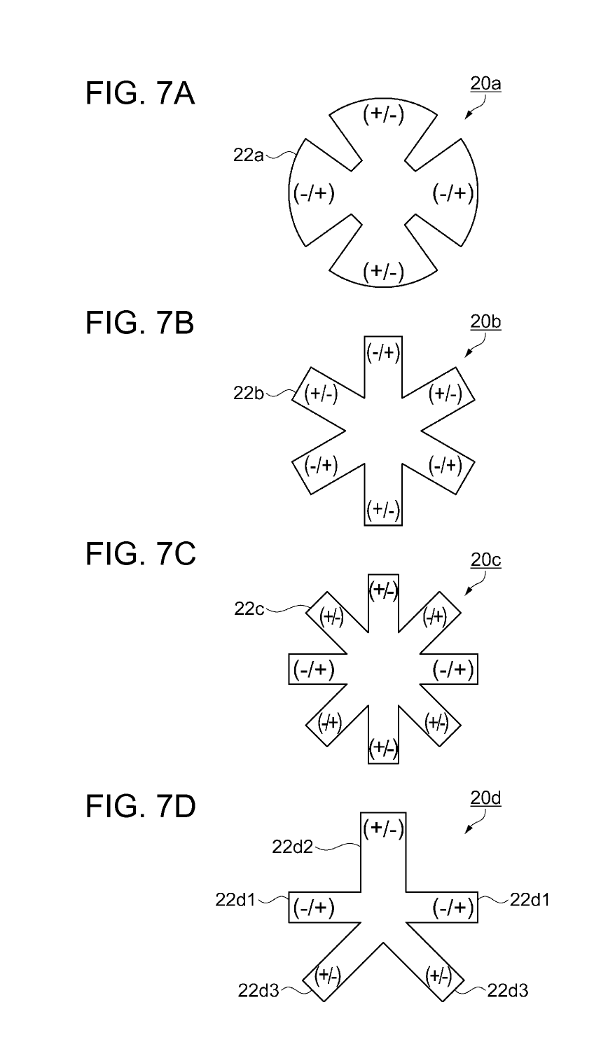

FIGS. 7A to 7D are plan views illustrating an example of a variation of the upper electrode in a vibrator according to Modification Example 1.

In the embodiment, as illustrated in FIG. 1A, the upper electrode 20 is described as the upper electrode 20 which shows a cross shape by the four vibration reeds 22 that extend from the base portion 21. However, the configuration is not limited thereto. The number of vibration reeds 22 may be an even number or an odd number, and four or more upper electrodes 20 may be formed.

FIG. 7A is a view illustrating an upper electrode 20a configured in a disc shape. When the vibration occurs so that phases of the vibration of vibration reeds 22a adjacent to each other are reversed, it is possible to provide a beam type vibrator having a high Q value in which the deterioration of the vibration efficiency and the vibration leakage are suppressed.

FIG. 7b is a view illustrating an upper electrode 20b having six vibration reeds 22b. When the vibration occurs so that phases of the vibration of the vibration reeds 22b adjacent to each other are reversed, it is possible to provide a beam type vibrator having a high Q value in which the deterioration of the vibration efficiency and the vibration leakage are suppressed.

FIG. 7C is a view illustrating an upper electrode 20c having eight vibration reeds 22c. When the vibration occurs so that phases of the vibration of the vibration reeds 22c adjacent to each other are reversed, or when two vibration reeds 22c adjacent to each other vibrate as one group in the same phase as illustrated in FIG. 7C, and the vibration occurs so that the phases of the vibration of the adjacent groups are reversed, it is possible to provide a beam type vibrator having a high Q value in which the deterioration of the vibration efficiency and the vibration leakage are suppressed.

FIG. 7D is a view illustrating an upper electrode 20d having five vibration reeds 22d. A vibration reed 22d2 and two vibration reeds 22d3 which pinch the base portion 21 at a facing position have different lengths (length in a width direction) of a direction which intersects a direction that extends from the base portion 21, and the length of a width direction of the vibration reed 22d2 is relatively longer than the length of a width direction of the two vibration reeds 22d3. This is to balance the vibration of the entire upper electrode 20b in which the base portion 21 and the vibration reeds 22d1, 22d2, and 22d3 are integrated in a vibration node portion. By this configuration, even when the total number of the vibration reeds 22d1, 22d2, and 22d3 is an odd number, it is possible to provide a beam type vibrator having a high Q value in which the deterioration of the vibration efficiency and the vibration leakage are suppressed.

### Modification Example 2

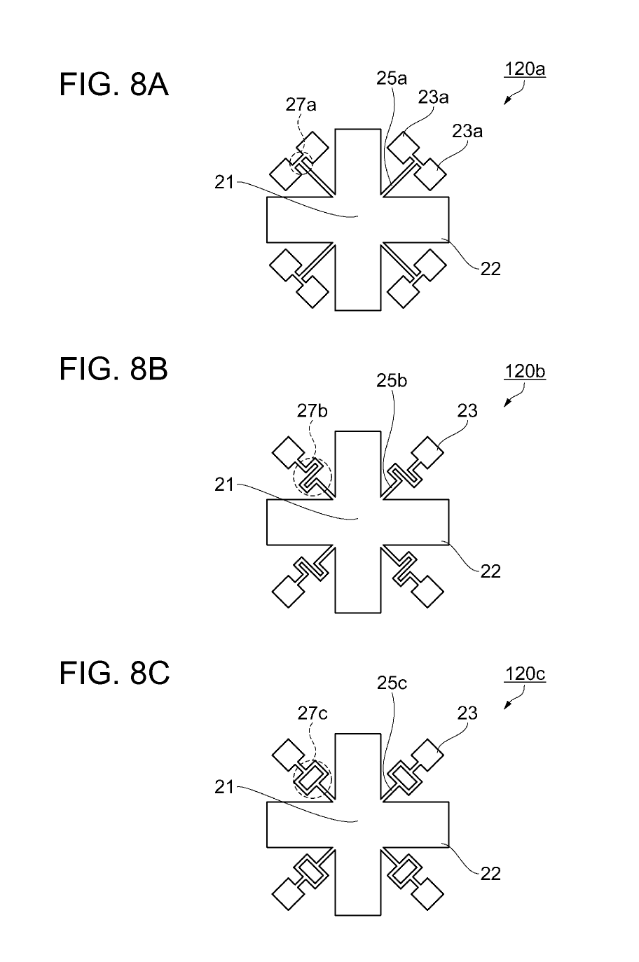

FIGS. 8A to 8C are plan views illustrating an example of a variation of the stress-relaxing portion in a vibrator according to Modification Example 2.

In the embodiment, as illustrated in FIG. 1A, the stress-relaxing portion 27 is configured to have a part which extends in a direction that intersects with a direction in which the supporting portion 25 extends. However, the configuration is not limited thereto. In addition, the stress-relaxing portion 27 is provided in all of the four supporting portions 25, but the embodiment is not limited thereto, and the stress-relaxing portion 27 may be provided in at least one supporting portion 25. For this reason, a structure may be employed in which the stress generated by the extension and contraction of the substrate 1 according to the change in the outer temperature can be suppressed.

FIG. 8A is a view illustrating the shape of a stress-relaxing portion 27a provided between the vibration node portion and a fixing portion 23a. The stress-relaxing portion 27a has a part which extends in a direction that intersects with a direction in which a supporting portion 25a extends. The part has a substantially rectangular shape which has a direction that intersects with a direction in which the supporting portion 25a extends as a longitudinal direction. The substantial center of the part is connected with the supporting portion 25a, and the fixing portions 23a are respectively connected to both ends of the part in the longitudinal direction of the part.

By using this shape, even when the stress generated by the extension and contraction of the substrate according to the change in the outside temperature is transmitted via the fixing portion 23a, a part of the stress-relaxing portion 27a is deformed like a plate spring, and it is possible to mitigate the transmission to the entire upper electrode 120a which is integrated by the base portion 21 and the vibration reed 22. For this reason, it is possible to provide the beam type vibrator which has a stable vibration characteristic with respect to the outer temperature change and high Q value.

FIG. 8B is a view illustrating a shape of a stress-relaxing portion 27b provided between the vibration node portion and a fixing portion 23. The stress-relaxing portion 27b has a plurality of parts which is bent in a direction that intersects with a direction in which a supporting portion 25b extends. The parts have three substantially rectangular parts which have a direction that intersects with a direction in which the supporting portion 25b extends as a longitudinal direction. In each part, both ends in the longitudinal direction are respectively connected to the part of a direction in which the supporting portion 25b extends.

By using this shape, even when the stress generated by the extension and contraction of the substrate according to the change in the outside temperature is transmitted via the fixing portion 23, the stress-relaxing portion 27b is deformed like a coil spring, and it is possible to mitigate the transmission to the entire upper electrode 120b which is integrated by the base portion 21 and the vibration reed 22. For this reason, it is possible to provide a beam type vibrator which has a stable vibration characteristic with respect to the outer temperature change and a high Q value.

FIG. 8C is a view illustrating a shape of a stress-relaxing portion 27c provided between the vibration node portion and a fixing portion 23. The stress-relaxing portion 27c has a plurality of parts which is bent in a direction that intersects with a direction in which a supporting portion 25c extends. The parts have two substantially rectangular parts which have a direction that intersects with a direction in which the supporting portion 25c extends as a longitudinal direction. In each part, both ends in the longitudinal direction are respectively connected to the part of a direction in which the supporting portion 25c extends, that is, the part has a shape including a substantially rectangular penetration portion at the substantially rectangular center part.

By using this shape, even when the stress generated by the extension and contraction of the substrate according to the change in the outside temperature is transmitted via the fixing portion 23, two parts of the stress-relaxing portion 27c are deformed like a plate spring, and it is possible to mitigate the transmission to the entire upper electrode 120c which is integrated by the base portion 21 and the vibration reed 22. For this reason, it is possible to provide a beam type vibrator which has a stable vibration characteristic with respect to the outer temperature change and a high Q value. In addition, the shape of the stress-relaxing portion 27c is a substantially rectangular shape which includes the direction in which the supporting portion 25 extends as a short-length direction, but may be a substantially rectangular shape which includes the direction in which the supporting portion 25 extends as a longitudinal direction.

### Modification Example 3

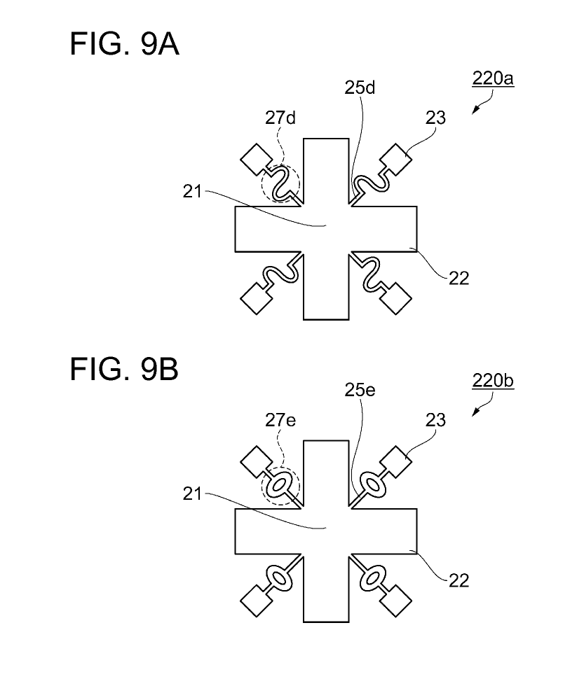

FIGS. 9A and 9B are plan views illustrating an example of a variation of the stress-relaxing portion in a vibrator according to Modification Example 3.

In the embodiment, as illustrated in FIG. 1A, in the stress-relaxing portion 27, apart which extends in a direction that intersects with a direction in which the supporting portion 25 extends is configured in a substantially linear shape, but the configuration is not limited thereto. In addition, the stress-relaxing portion 27 is provided in all of the four supporting portions 25, but the embodiment is not limited thereto, and the stress-relaxing portion 27 may be provided in at least one supporting portion 25. For this reason, a structure may be employed in which the stress generated by the extension and contraction of the substrate 1 according to the change in the outer temperature can be suppressed.

FIG. 9A is a view illustrating a shape of a stress-relaxing portion 27d provided between the vibration node portion and the fixing portion 23. The stress-relaxing portion 27d has a part of a curved portion which has a shape that extends in a curve shape in a direction in which a supporting portion 25d extends. By using this shape, even when the stress generated by the extension and contraction of the substrate according to the change in the outside temperature is transmitted via the fixing portion 23, a part of the stress-relaxing portion 27d is deformed like a coil spring, and it is possible to mitigate the transmission to an upper electrode 220a which is integrated by the base portion 21 and the vibration reed 22. For this reason, it is possible to provide a beam type vibrator which has a stable vibration characteristic with respect to the outer temperature change and a high Q value.

FIG. 9B is a view illustrating the shape of a stress-relaxing portion 27e provided between the vibration node portion and the fixing portion 23. The stress-relaxing portion 27e has a ring-shaped annular portion. By using this shape, even when the stress generated by the extension and contraction of the substrate 1 according to the change in the outside temperature is transmitted via the fixing portion 23, a part of the stress-relaxing portion 27e is deformed, and it is possible to mitigate the transmission to the entire upper electrode 220b which is integrated by the base portion 21 and the vibration reed 22. For this reason, it is possible to provide a beam type vibrator which has a stable vibration characteristic with respect to the outer temperature change and a high Q value. In addition, the ring shape is a short elliptical shape in a direction in which the supporting portion 25e extends, but may be a long elliptical shape in the direction in which the supporting portion 25e extends.

### Modification Example 4

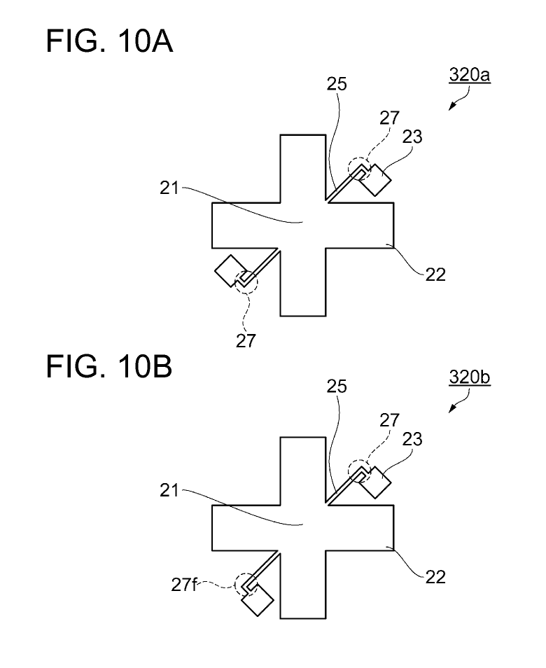

FIGS. 10A and 10B are plan views illustrating examples of variations of a stress-relaxing portion having two supporting portions in a vibrator according to Modification Example 4.

In the embodiment, as illustrated in FIG. 1A, four supporting portions 25 which have the stress-relaxing portion 27 are provided, but the number of the supporting portions 25 is not limited to four. At least two or more supporting portions 25 may be disposed to pinch the base portion 21 at a facing position. For this reason, a structure may be employed in which the stress generated by the extension and contraction of the substrate 1 according to the change in the outer temperature can be suppressed.

FIG. 10A is a view illustrating the shape of the stress-relaxing portion 27 which has two supporting portions 25 and is provided between the vibration node portion and the fixing portion 23. The shape of the stress-relaxing portion 27 is the same as the shape of the embodiment illustrated in FIG. 1A. Since the number of the supporting portions 25 is two, the stress generated by the extension and contraction of the substrate according to the change in the outside temperature is only in one direction, the stress transmitted to the entire upper electrode 320a which is integrated by the base portion 21 and the vibration reed 22 is reduced, a part of the stress-relaxing portion 27 is deformed like a spring, and it is possible to mitigate the stress. For this reason, it is possible to provide a beam type vibrator which has a more stable vibration characteristic with respect to the outer temperature change and a higher Q value.

FIG. 10B is a view illustrating the shape of a stress-relaxing portion 27f which has two supporting portions 25 and is provided between the vibration node portion and the fixing portion 23 of one of the supporting portions 25. The shape of the stress-relaxing portion 27 provided in the other supporting portion 25 is the same as the shape of the embodiment illustrated in FIG. 1A. The shape of the stress-relaxing portion 27f provided in one supporting portion 25 extends in a direction which intersects with a direction in which the supporting portion 25 extends, which is the same direction as the stress-relaxing portion 27 provided in the other supporting portion 25.

By using this shape, an outer stress applied to the adjacent vibration reed 22 is the same, and it is possible to reduce a distortion generated by a difference of the outer stress applied to each vibration reed 22. For this reason, it is possible to further suppress the vibration leakage. In addition, even when the stress generated by the extension and contraction of the substrate according to the change in the outside temperature is transmitted via the fixing portion 23, the stress-relaxing portions 27 and 27f are deformed like a spring, and it is possible to mitigate the transmission to the entire upper electrode 320b which is integrated by the base portion 21 and the vibration reed 22. Accordingly, it is possible to provide a beam type vibrator which has a stable vibration characteristic with respect to the outer temperature change and a higher Q value.

The entire disclosure of Japanese Patent Application No. 2013-210773, filed Oct. 8, 2013 is expressly incorporated by reference herein.

What is claimed is:

1. A vibrator, comprising:
a substrate;
a fixing portion which is fixed above the substrate;
a base portion which is spaced and disposed above the substrate;
a vibration reed which extends in a direction along the substrate from the base portion; and
a supporting portion which connects the fixing portion and a connecting portion between the base portion and the vibration reed.

2. The vibrator according to claim 1,
wherein, in a planar view of the substrate, the base portion is present between the plurality of supporting portions.

3. The vibrator according to claim 2,
wherein at least one supporting portion is provided with a stress-relaxing portion.

4. The vibrator according to claim 3,
wherein, in a planar view of the substrate, the plurality of stress-relaxing portions is bent in the same rotating direction with respect to the center of the base portion.

5. The vibrator according to claim 3,
wherein the stress-relaxing portion includes a plurality of regions which is bent in a direction that intersects with a direction in which the supporting portion extends from the base portion.

6. The vibrator according to claim 3,
wherein the stress-relaxing portion has a curved portion.

7. The vibrator according to claim 3,
wherein the stress-relaxing portion has an annular portion.

8. The vibrator according to claim 3,
wherein the stress-relaxing portions of the two supporting portions which are disposed to pinch the base portion at a facing position, are bent in a direction along each other.

9. The vibrator according to claim 1,
wherein, in a planar view of the substrate, the two adjacent vibration reeds are different from each other in a phase of the vibration.

10. The vibrator according to claim 1,
wherein the plurality of vibration reeds, which has different lengths of the width direction from each other, is provided.

11. An oscillator, comprising:
the vibrator according to claim 1.

12. An electronic device, comprising:
the vibrator according to claim 1.

13. A moving object, comprising;
the vibrator according to claim 1.
